(19) United States
(12) Patent Application Publication
(10) Pub. No.: US 2012/0098002 A1
(43) Pub. Date: Apr. 26, 2012

(54) Organic light emitting device

(76) Inventors: Jung-Bae Song, Yongin-City (KR); Sang-Pil Lee, Yongin-city (KR); Young-Rok Song, Yongin-city (KR)

(21) Appl. No.: 13/137,138

(22) Filed: Jul. 22, 2011

(30) Foreign Application Priority Data
Oct. 22, 2010 (KR) 10-2010-0103502

(51) Int. Cl. H01L 33/50

(52) U.S. Cl. 257/98; 257/E33.067

(57) ABSTRACT

An organic light emitting device includes first and second electrodes facing each other, and an emission layer disposed between the first and second electrodes. The emission layer is configured to display light having a first color with a first wavelength region. The emission layer includes a host material configured to display light having a second color with a second wavelength region, and the second wavelength region is shorter than the first wavelength region. The emission layer also includes first and second color dopant materials mixed within the host material.

### BACKGROUND

1. Field

Embodiments relate to an organic light emitting device.

2. Description of the Related Art

An organic light emitting device may include two electrodes facing each other and an organic emission layer interposed between the two electrodes. An organic light emitting device may emit a light, e.g., when holes injected from one electrode are combined with electrons injected from the other electrode in an organic emission layer to generate excitons and release energy. An organic light emitting device may be applied to various fields including, e.g., a display device and an illuminator. An efficiency of an organic light emitting device may be improved by, e.g., decreasing a driving voltage. The light emitting characteristics of the organic light emitting device may also be improved.

### SUMMARY

Embodiments are directed to an organic light emitting device having a low driving voltage and improved light emitting characteristics.

An embodiment may provide an organic light emitting device including first and second electrodes facing each other and an emission layer disposed between the first and second electrodes and displaying a first color. The emission layer may include a second color host material with a shorter wavelength region than a first color host material and first and second color dopant materials mixed with the second color host material.

The first and second color dopant materials may each be a phosphorescent material.

The second color dopant material may have a higher triplet energy level than the first color dopant material.

The second host material may have a higher triplet energy level than the second color dopant material. The host material may have a triplet energy level greater than about 2.4 eV or more.

The host material may include at least one 4,4′-N,N′-dicarbazole biphenyl (CBP), and 2,9-dimethyl-4,7-diphenyl-1,10-phenanthroline (BCP).

The first color dopant material may include at least one tris(1-phenyl quinoline iridium (PQIr), bis(2-2-benzo[4,5-a]thienyl)pyridinato-N,C3) iridium (BTPIr), and octaethylporphyrin platinum (PtOEP).

The second color dopant material may include at least one of bis(2-phenylpyridinato-(N,C2′)iridium(acetyl-acetonate) (Ir(ppy)2(acac)), and fac-tris(2-phenylpyridine)iridium(Ir(ppy)₃).

The first color may be red, and the second color may be green.

An amount of the first color dopant material may be about 1 vol. % to about 5 vol. % based on a volume of the host material. An amount of the second color dopant material may be about 5 vol. % to about 20 vol. % based on a volume of the host material.

The organic light emitting device may include at least one assistant layer, each assistant layer may be between one of: the first electrode and the emission layer, and the second electrode and the emission layer

Embodiments may provide an organic light emitting device with lower driving voltage and driving electric power.

### BRIEF DESCRIPTION OF THE DRAWINGS

FIG. 1 illustrates a cross-sectional view showing an organic light emitting device according to an exemplary embodiment;

FIG. 2 illustrates a schematic diagram enlarging a region A of FIG. 1, according to an exemplary embodiment,

FIG. 3 illustrates a drawings showing one effect of an experimental example,

FIGS. 4A and 4B illustrate drawings showing effects of an experimental example relative to a comparative example.

### DETAILED DESCRIPTION

Korean Patent Application No. 10-2010-0103502, filed on Oct. 22, 2010, in the Korean Intellectual Property Office, and entitled: “Organic Light Emitting Device,” is incorporated by reference herein in its entirety.

Example embodiments will now be described more fully hereinafter with reference to the accompanying drawings; however, they may be embodied in different forms and should not be construed as limited to the embodiments set forth herein. Hereinafter, organic light emitting devices according to embodiments are described. The following embodiments are provided so that a person of an ordinary skill in the art may understand this disclosure, which is not limited thereto. As those skilled in the art would realize, the described embodiments may be modified in various different ways, all without departing from the spirit or scope of this disclosure.

In this specification, it will be understood that when one constituent element is referred to as being “on” another constituent element, it can be directly on the other element or intervening elements may also be present. In this specification, the term “and/or” refers to at least one of listed constituent elements. In this specification, constituent elements and/or portions are depicted using the words “first”, “second”, and the like, which are used for definite description.

In the drawings, the thicknesses and/or relative thicknesses of constituent elements are exaggerated for clarity. The terms indicating positions such as “upper” and “under” are used for definite description of relative positions, and do not indicate absolute positions of constituent elements.

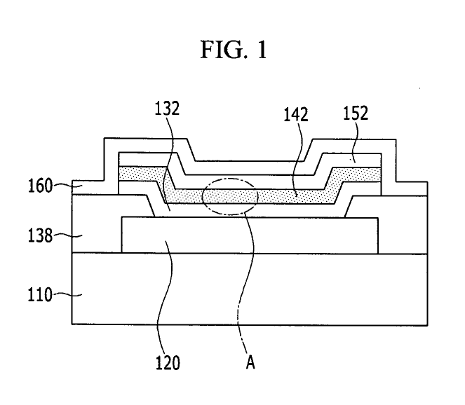

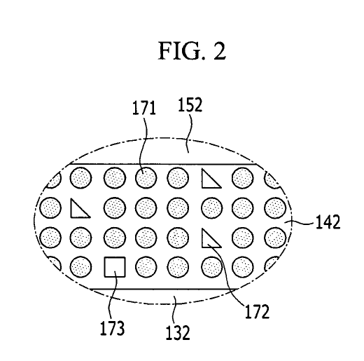

Referring to FIGS. 1 and 2, an organic light emitting device according to an exemplary embodiment is described.

According to an exemplary embodiment, an organic light emitting device may include a plurality of pixels. The plurality of pixels may include adjacent pixels that display colors that are differ from each other. For example, the plurality of pixels may include at least one of a red pixel displaying a red color, a green pixel displaying a green color, and a blue pixel displaying a blue color. However, the pixels are not limited thereto, e.g., the plurality of pixels many include other various types and/or colors of pixels.

FIG. 1 illustrates a cross-sectional view showing an exemplary stacking structure of one pixel in an organic light emitting device, according to an exemplary embodiment. FIG. 2 illustrates a schematic diagram enlarging a region A in FIG. 1. Hereinafter, a red pixel is illustrated as an example; however embodiments are not limited thereto.

Referring to FIG. 1, the red pixel may include a lower electrode 120, a red emission layer 142, and an upper electrode 160 sequentially laminated on a substrate 110. According to an exemplary embodiment, the red emission layer 142 may be composed to emit a light with a center wavelength, e.g., a red light in a region ranging from about 560 nm to about 780 nm.

The red pixel may include a lower auxiliary layer 132 disposed between the lower electrode 120 and the red emission layer 142. An upper auxiliary layer 152 may be disposed between the red emission layer 142 and the upper electrode 160.

The lower electrode 120 may be an anode or a cathode. According to an exemplary embodiment, illustrated is an anode as the lower electrode 120 for better understanding and ease of description, but a cathode as the lower electrode 120 may be applied thereto.

The lower electrode 120 may be, e.g., a transparent or opaque electrode. For example, the lower electrode 120 may be made of ITO, IZO, or a combination thereof; or of aluminum (Al), silver (Ag), or a combination thereof.

The lower electrode 120 may be electrically insulated from the lower electrodes (not shown) positioned in neighboring pixels. For example, the insulating patterns 138 may be positioned at both sides of the lower electrode 120.

When the lower electrode 120 is an anode, the lower auxiliary layer 132 may include at least one of a hole injection layer (HIL) and a hole transport layer (HTL). The hole injection layer (HIL) and the hole transport layer (HTL) may be sequentially laminated in plural on the lower electrode 120. The hole injection layer (HIL) and hole transport layer (HTL) may be disposed in at least a pair of layers, as a single layer, or omitted.

When the lower electrode 120 is a cathode, the lower auxiliary layer 132 may include at least one of an electron injection layer (EIL) and an electron transport layer (ETL).

Referring to FIG. 2, the red emission layer 142 may include a host material 171, and a plurality of dopants, e.g., the two dopant materials 172 and 173, mixed in the host material 171. The dopant materials 172 and 173 may mixed with the host material 171 and dispersed substantially throughout the entire emission layer 142.

The host material 171 may emit light with a shorter wavelength region than a wavelength region of red color light. For example, the host material may include a green and/or blue host material. For example, the host material may be a green host material that has a wavelength region that is similar to, e.g., near, the wavelength region of red color light. The green host material may emit light with a shorter wavelength region that the wavelength region of the red color light.

The dopant materials 172 and 173 may be, e.g., a green dopant material 172 and a red dopant material 173, respectively. Without intending to be bound by this theory, there may be easy Dexter energy transfer from the green dopant material 172 to the red dopant material 173. The green and red dopant materials 172 and 173 may each be and/or include a phosphorescent material.

The host material 171, e.g., a green host material 171, may have a higher triplet energy level than the green and red dopant materials 172 and 173. For example, the green host material 171 may have a triplet energy level of more than about 2.4 eV. The green host material 171 may include 4,4′-N,N′-dicarbazolebiphenyl (CBP), 2,9-dimethyl-1,10-phenantrolline (BCP), or a combination thereof.

The green dopant material 172 may be selected from, e.g., green phosphorescent dopant materials. The green phosphorescent dopant materials may have a lower triplet energy level than the green host material 171. For example, the green dopant material 172 may include iridium (III) bis(2-phenylpyridinato-N,C2′)acetyl-acetonate (Ir(ppy)2(acac)), iridium (III) fac-tris(2-phenylpyridinato-N,C2′ (Ir(ppy)₃), or a combination thereof.

The red dopant material 173 may be selected from, e.g., red phosphorescent dopant materials. The red phosphorescent dopant materials may have a lower triplet energy level than the green host material 171 and the green dopant material 172. For example, the red dopant material 173 may include bis(2-phenylbenzothiazole)iridium acetylacetonate (BTIr), tris(1-phenyl quinoline iridium (PQIr), bis(2-2′-benzo[4,5-a]thienyl)pyridinato-N,C3)iridium (BTPIr), octaethylporphyrin platinum (PtOEP), or a combination thereof.

The emission layer 142 including the green host material 171, the green dopant material 172, and the red dopant material 173 may emit a red light therefrom. Without intending to be bound by this theory, the green host material 171 and the green and red dopant materials 172 and 173 may have an energy level relationship. For example, energy may be transferred from the green host material 171 to the green dopant material 172 and from the green dopant material 172 to the red dopant material 173. In particular, the green host material 171 may have a higher triplet energy level than the green and red dopant materials 172 and 173. The green dopant material 172 may have a higher triplet energy level than the red dopant material 173. When the emission layer 142 generates excitons, energy may be transferred between the green host material 171 and the green dopant material 172 and between the green dopant material 172 and the red dopant material 173.

The green dopant material 172 may be included in an amount of about vol. % to about 20 vol. % against the green host material 171. The green dopant material 172 may be included in an amount of about 5 vol. % to about 20 vol. % based on a total volume of the green host material 171 in the red emission layer 142. The amount of the green dopant material 172 may be within another range within the range of 5 vol. % to about 20 vol. %, e.g., the another range may include, but is not limited to, e.g., about 10 vol. % to about 15 vol. %; about 7 vol. % to about 12 vol. %; and about 12 vol. % to about 15 vol. %. Without intending to be bound by this theory, when the green dopant material 172 is included, there may be efficient energy transfer between the green host material 171 and the green dopant material 172. The efficient energy transfer may improve a luminous efficiency, decrease interaction among the green dopant materials 172, and minimized, reduce, and/or prevent deterioration of the luminous efficiency.

The red dopant material 173 may be included in an amount of about 1 vol. % to about 5 vol. % against the green host material 171. The red dopant material 173 may be included in an amount of about 1 vol. % to about 5 vol. % based on the total volume of the green host material 171 in the red emission layer 142. The amount of red dopant material 173 may be within another range within the range of 1 vol. % to about 5 vol. %, e.g., the another range may include, but is not limited to, e.g., about 2 vol. % to about 4 vol. %; and about 3 vol. % to about 4 vol. %. Without intending to be bound by this theory, when the red dopant material 173 is included, the green dopant material 172 may be sufficiently closer to the red dopant material 173, and bring about efficient energy transfer between the green and red dopant materials 172 and 173. Big interaction may decrease among red dopant materials 173 and deterioration of the luminous efficiency may be minimized, reduced, and/or prevented.

The emission layer 142 including the green host material 171 and the green and red dopant materials 172 and 173 may emit a red light due to, e.g., energy transfer between host and dopant materials and/or dopant materials as aforementioned. Without intending to be bound by this theory, the emission layer 142 may overcome a limit of a red phosphorescent material with low mobility. Thus, a display may emit a red light from a green phosphorescent material with a higher mobility, and may resultantly decrease driving voltage.

In addition, as described above, the emission layer 142 may emit a light within the red wavelength region due to, e.g., efficient energy transfer between the respective green and red dopant materials 172 and 173. Accordingly, an organic light emitting device including the emission layer 142 may have, e.g., improved light emitting characteristic. The effects of an organic light emitting device according to an exemplary embodiment are illustrated later through experiments referring to the exemplary experimental data.

A red pixel including, e.g., the green host material 171 and the green and red dopant materials 172 and 173, is illustrated as an example. A green pixel may be formed the same, e.g., including the host material 171 and the dopant materials 172 and 173 dispersed in the host material 171.

As for a green pixel, the emission layer 142 may include, e.g., a blue host material as the host material 171, a blue dopant material as the dopant material 172, and a green dopant material as the dopant material 173. The host material 171, e.g., the blue host material, may emit light with a shorter wavelength region than a wavelength region of green color light. For example, the emission layer 142 may include 9H-carbazole-9,9′-(1,3-phenylene)-bis-9C1) (MCP) as the blue host material and bis(4,6-difluorophenylpyridinato-N,C2, picolinato iridium (FirPic) as the blue dopant material. The green dopant material may include iridium (III) bis(2-phenylpyridinato-N,C2′)acetyl-acetonate (Ir(ppy)2(acac)), iridium (III) fac-tris(2-phenylpyridinato-N,C2′ (Ir(ppy)3), or a combination thereof. The emission layer 142 for a green pixel may emit a light with a green wavelength region due to, e.g., Dexter energy transfer between the blue and green dopant materials.

The green pixel may be the same as the red pixel as aforementioned in detail. However, the green pixel may include an emission layer 142 that includes a blue host material, a blue dopant material, and a green dopant material. The red pixel may include an emission layer 142 that includes a green host material, a green dopant material, and a red dopant material.

Referring to FIG. 1, according to an exemplary embodiment, when the upper electrode 160 is a cathode, an upper auxiliary layer 152 on the red emission layer 142 may include an electron injection layer (EIL) and/or an electron transport layer (ETL). The electron injection layer (EIL) and the electron transport layer (ETL) may be a plurality of layers sequentially laminated on the emission layer 142. However, the hole injection layer (HIL) and the hole transport layer (HTL) may be a single layer or omitted.

Referring to FIG. 1, according to an exemplary embodiment, pixels for an organic light emitting device may be fabricating using a method to form the structure illustrated in FIG. 1. The aforementioned constituent elements may not be illustrated.

Referring to FIG. 1, according to an exemplary embodiment of fabricating a red and/or green pixel, the lower electrode 120 may be disposed on the substrate 110. The lower electrode 120 may be fabricated by disposing a conductive layer including, e.g., ITO, IZO, or a combination thereof on the substrate 110. The conductive layer may be patterned to form the lower electrode 120.

The lower electrode 120 may include, e.g., insulating patterns 138 on both sides of the substrate 110, e.g., lateral ends of the lower electrode 120 may be surrounded by the insulating patterns 138. The insulating patterns 138 may be a structure insulting the lower electrode 120 from other neighboring electrodes.

According to an exemplary embodiment, a shadow mask (not shown) may be formed to selectively expose the top of the lower electrode 120. Then, the lower auxiliary layer 132, the emission layer 142, and the upper auxiliary layer 152 may be sequentially disposed on the exposed lower electrode 120.

The emission layer 142 for a red pixel may be formed by coating a mixture including, e.g., the green host material, the green dopant material, and the red dopant material on the lower electrode 120 and/or the lower auxiliary layer 132. The mixture may include only the green host material and the green and red dopant materials, or may include other materials therein. The emission layer 142 for a green pixel may be formed by coating a mixture including, e.g., the blue host material, the blue dopant material, and the green dopant material on the lower electrode 120 or the lower auxiliary layer 132. The mixture may include only the blue host material and the blue and green dopant materials, or may include other materials therein.

The green host material may have a higher triplet energy level than the green and red dopant materials. The green dopant material may have a higher triplet energy level than the red dopant material. For example, the green host material may have a higher triplet energy level than about 2.4 eV or more. The green and red dopant materials may have a lower triplet energy level than about 2.4 eV or more.

An upper electrode 160 may be disposed on the red emission layer 142 or the upper auxiliary layer 152 formed on the red emission layer 142. The upper electrode 160 may cover a red pixel area including the emission layer 142 and other color pixel areas.

Embodiments will be described in detail through the following exemplary experimental examples. The following exemplary examples are merely described for the purpose of explanation without limiting the scope of the embodiments.

<Fabrication of an Organic Light Emitting Device>

### Experimental Example

ITO was laminated on a glass substrate and then patterned. HT01 (Lu-dis Corporation) was deposited to be 65 nm thick thereon as a hole injection layer (HIL), L101 (LG Chem. Ltd.) was deposited to be 5 nm thick as a second hole injection layer (HIL) thereon, and HT320 (Idemitsu Kosan) was deposited to be 140 nm thick as a hole transport layer thereon. Then, an emission layer was laminated thereon to be 40 nm thick by using a mixture of 10 wt % of GD48, an exemplary green dopant material, and 4 wt % of RD26, an exemplary red dopant material, in NS60 (UDC), an exemplary host material, using a ternary co-evaporation method. Then, LiQ:LG201 (LG Chem. Ltd. 1:1) was deposited to be 30 nm thick as an electron transport layer, and Al was deposited thereon as an upper electrode.

### Comparative Example

An organic light emitting device was fabricated according to the same method as Experimental Example except for using a mixture of GRH16 (Lu-dis Corporation) and 8 wt % of RD 26 (UDC) to be 40 nm thick for an emission layer.

First Evaluation

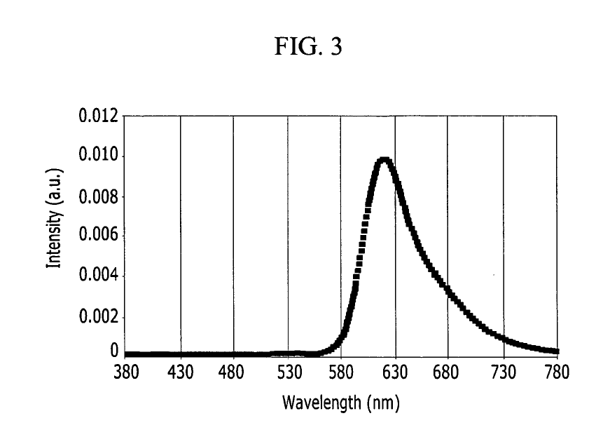

Referring to FIG. 3, light emitting characteristics of an organic light emitting device according to the Experimental Example is illustrated.

FIG. 3 is a graph showing strengths of the organic light emitting device of the Experimental Example depending on wavelengths.

Referring to FIG. 3, the red emission layer according to the Experimental Example emits a light with a strong-enough degree in a red wavelength region, e.g., ranging from about 580 to 730 nm. In other words, FIG. 3 shows efficient energy transition between the green and red dopant materials in the red emission layer.

Second Evaluation

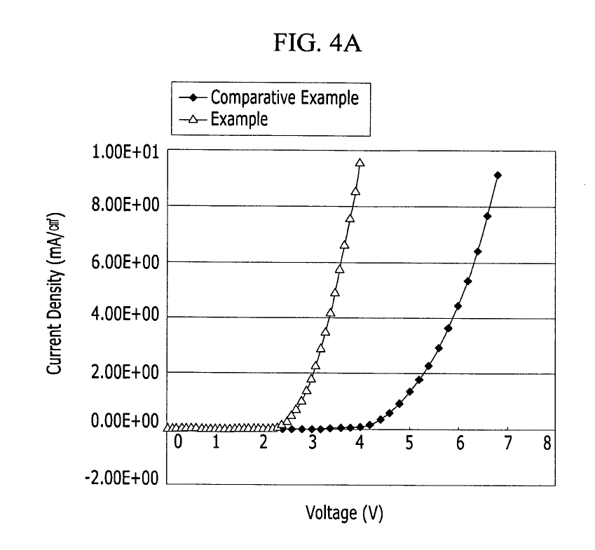

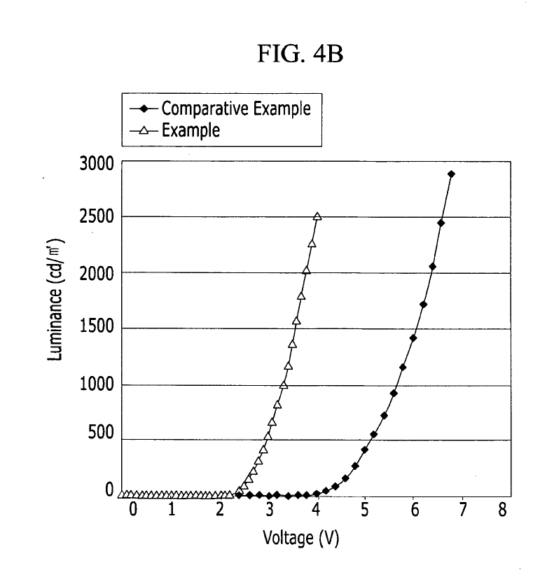

Referring to FIGS. 4A and 4B, light emitting characteristic of an organic light emitting device according to the Experimental Example is illustrated relative to light emitting characteristics of an organic light emitting device according to the Comparative Example.

FIG. 4A is a graph showing current density against voltage of organic light emitting devices according to the Experimental Example and the Comparative Example. FIG. 4B is a graph showing luminance against voltage of the organic light emitting devices according to the Experimental Example and the Comparative Example.

Referring to FIG. 4A, an organic light emitting device according to the Experimental Example may have current density at a lower driving voltage compared with the Comparative Example.

Referring to FIG. 4B, the organic light emitting device of the Experimental Example may have high luminance at the same voltage compared with the Comparative Example.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An organic light emitting device, comprising:
first and second electrodes facing each other; and
an emission layer disposed between the first and second electrodes, the emission layer being configured to display light having a first color with a first wavelength region, wherein the emission layer includes:
a host material configured to display light having a second color with a second wavelength region, the second wavelength region being shorter than the first wavelength region, and
first and second color dopant materials mixed within the host material.

2. The organic light emitting device of claim 1, wherein the first and second color dopant materials are each a phosphorescent material.

3. The organic light emitting device of claim 1, wherein the second color dopant material has a higher triplet energy level than the first color dopant material.

4. The organic light emitting device of claim 3, wherein the host material has a higher triplet energy level than the second color dopant material.

5. The organic light emitting device of claim 4, wherein the host material has a triplet energy level greater than or equal to about 2.4 eV.

6. The organic light emitting device of claim 5, wherein the host material includes at least one of 4,4′-N,N′-dicarbazole biphenyl (CBP) and 2,9-dimethyl-4,7-diphenyl-1,10-phenanthroline (BCP).

7. The organic light emitting device of claim 6, wherein the first color dopant material includes at least one of bis(2-phenylbenzothiazole)iridium acetylacetonate (BTIr), tris(1-phenyl quinoline iridium (PQIr), bis(2-2-benzo[4,5-a]thienyl)pyridinato-N,C3) iridium (BTPIr), and octaethylporphyrin platinum (PtOEP).

8. The organic light emitting device of claim 7, wherein the second color dopant material includes at least one of bis(2-phenylpyridinato-(N,C2′)iridium(acetyl-acetonate) (Ir(ppy)2(acac)), and fac-tris(2-phenylpyridine)iridium (Ir(ppy)₃).

9. The organic light emitting device of claim 1, wherein the first color is red and the second color is green.

10. The organic light emitting device of claim 1, wherein an amount of the first color dopant material is about 1 vol. % to about 5 vol. % based on a volume of the host material.

11. The organic light emitting device of claim 1, wherein an amount of the second color dopant material is about 5 vol. % to about 20 vol. % based on a volume of the host material.

12. The organic light emitting device of claim 1, further comprising at least one assistant layer, each assistant layer being between one of: the first electrode and the emission layer, and the second electrode and the emission layer.
